(19) United States
(12) Patent Application Publication
(10) Pub. No.: US 2026/0360403 A1
(43) Pub. Date: Nov. 12, 2026

(54) ACTIVE CONTROL CIRCUIT AND SEMICONDUCTOR MEMORY APPARATUS INCLUDING THE ACTIVE CONTROL CIRCUIT

(71) Applicant: SK hynix Inc., Icheon-si Gyeonggi-do (KR)

(72) Inventors: Woong Rae KIM, Icheon-si Gyeonggi-do (KR); Min Jun CHOI, Icheon-si Gyeonggi-do (KR)

(73) Assignee: SK hynix Inc., Icheon-si Gyeonggi-do (KR)

(21) Appl. No.: 19/271,190

(22) Filed: Jul. 16, 2025

(30) Foreign Application Priority Data
May 8, 2025 (KR) 10-2025-0059784

(51) Int. Cl. G11C 11/406; G11C 11/408; G11C 11/4091

(52) U.S. Cl. CPC G11C 11/40615; G11C 11/40622; G11C 11/4085; G11C 11/4087; G11C 11/4091

(57) ABSTRACT

An active control circuit includes an active signal generation circuit and an address control circuit. The active signal generation circuit generates a plurality of row active signals and a plurality of timing-adjusted row active signals by selectively combining an active command, a timing-adjusted refresh command, an active bank address signal, and a refresh bank address signal. The address control circuit generates an active address signal, the active bank address signal, the refresh bank address signal, and a refresh address signal according to an address signal and the refresh command, and outputs, according to the active command, a signal selected from the active address signal and the refresh address signal as a row address signal.

### CROSS-REFERENCES TO RELATED APPLICATION

The present application claims priority under 35 U.S.C. § 119(a) to Korean application number 10-2025-0059784 filed on May 8, 2025, in the Korean Intellectual Property Office, the entire contents of which application is incorporated herein by reference.

### BACKGROUND

### 1. Technical Field

Various embodiments generally relate to a semiconductor circuit, and, more particularly, to an active control circuit and a semiconductor memory apparatus including the active control circuit, that are capable of compensating for operation timing margins between different memory banks.

### 2. Related Art

A semiconductor memory apparatus includes a plurality of unit memory regions, for example, a plurality of memory banks. The plurality of memory banks must operate within a time interval defined by an operation specification. As the integration level of the semiconductor memory apparatus increases and the operation speed becomes faster, the time interval becomes shorter.

For example, when an active operation of a first memory bank, a refresh operation of a second memory bank, and an active operation of a third memory bank are sequentially performed, a timing margin between each operation may be insufficient, so that an operation interval of a bitline sense amplifier of the first memory bank overlaps with that of a bitline sense amplifier of the second memory bank, thereby causing a problem of a sensing operation error of the bitline sense amplifiers.

### SUMMARY

In an embodiment, an active control circuit may include an active signal generation circuit and an address control circuit. The active signal generation circuit may be configured to generate a plurality of row active signals and a plurality of timing-adjusted row active signals by selectively combining an active command, a timing-adjusted refresh command, an active bank address signal, and a refresh bank address signal. The address control circuit may be configured to generate an active address signal, the active bank address signal, the refresh bank address signal, and a refresh address signal according to an address signal and a refresh command, and may be configured to output, according to the active command, a signal selected from the active address signal and the refresh address signal as a row address signal.

In an embodiment, a semiconductor memory apparatus may include a plurality of memory banks and an active control circuit. The plurality of memory banks may be configured to perform a row active operation corresponding to a row address signal according to a plurality of row active signals and a plurality of timing-adjusted row active signals. The active control circuit may be configured to selectively combine an active command, a timing-adjusted refresh command, an active bank address signal, and a refresh bank address signal to generate the plurality of row active signals and the plurality of timing-adjusted row active signals.

In an embodiment, a semiconductor memory apparatus may include an active control circuit, a memory cell array, a latch, and a row decoder. The active control circuit may be configured to selectively combine an active command, a timing-adjusted refresh command, an active bank address signal, and a refresh bank address signal to generate a plurality of row active signals and a plurality of timing-adjusted row active signals. The memory cell array may be arranged with a plurality of wordlines and a plurality of bitlines. The latch may be configured to latch a row address signal according to a first row active signal among the plurality of row active signals, and may be configured to output the latched signal as a timing-adjusted row address signal according to a first timing-adjusted row active signal among the plurality of timing-adjusted row active signals. The row decoder may be configured to activate a wordline corresponding to the timing-adjusted row address signal among the plurality of wordlines when at least one of the first row active signal and the first timing-adjusted row active signal is activated.

### BRIEF DESCRIPTION OF THE DRAWINGS

FIG. 1 is a diagram illustrating a configuration of an active control circuit according to an embodiment of the present disclosure.

FIG. 2 is a diagram illustrating a configuration of an active signal generation circuit of FIG. 1 according to an embodiment of the present disclosure.

FIG. 3 is a diagram illustrating a configuration of a signal combination circuit of FIG. 2 according to an embodiment of the present disclosure.

FIG. 4 is a diagram illustrating a configuration of an address control circuit of FIG. 1 according to an embodiment of the present disclosure.

FIG. 5 is a diagram illustrating a configuration of an address latch circuit of FIG. 1 according to an embodiment of the present disclosure.

FIG. 6 is a diagram illustrating a configuration of a semiconductor memory apparatus according to an embodiment of the present disclosure.

FIG. 7 is a diagram illustrating a configuration of a memory bank of FIG. 6 according to an embodiment of the present disclosure.

### DETAILED DESCRIPTION

Various embodiments can compensate for insufficient timing margins between different memory banks, thereby preventing or mitigating a sensing operation error of a bitline sense amplifier and improving the operational reliability of a semiconductor memory apparatus.

Hereinafter, embodiments of the present disclosure will be described in more detail with reference to the accompanying drawings.

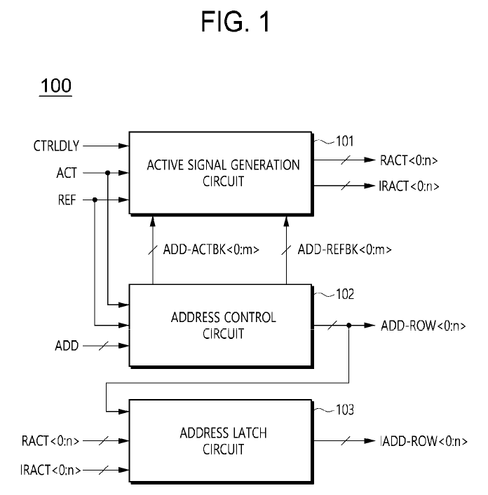

FIG. 1 is a diagram illustrating a configuration of an active control circuit 100 according to an embodiment of the present disclosure.

Referring to FIG. 1, the active control circuit 100 may include an active signal generation circuit 101 and an address control circuit 102. The active control circuit 100 may further include an address latch circuit 103.

The active signal generation circuit 101 may receive a delay control signal CTRLDLY, an active command ACT, a refresh command REF, an active bank address signal ADD-ACTBK<0:m>, and a refresh bank address signal ADD-REFBK<0:m>, and may output a plurality of row active signals RACT<0:n> and a plurality of timing-adjusted row active signals IRACT<0:n>.

The active signal generation circuit 101 may generate the row active signals RACT<0:n> and the plurality of timing-adjusted row active signals IRACT<0:n> by selectively combining an active command (ACT), a refresh command (REF), a signal obtained by delaying the refresh command (REF) according to the delay control signal (CTRLDLY), the active bank address signal (ADD-ACTBK<0:m>), and the refresh bank address signal (ADD-REFBK<0:m>).

The address control circuit 102 may receive the refresh command REF, the active command ACT, and an address signal ADD, and may output a row address signal ADD-ROW<0:n>, the active bank address signal ADD-ACTBK<0:m>, and the refresh bank address signal ADD-REFBK<0:m>.

The address control circuit 102 may decode the address signal ADD to generate an active address signal, the active bank address signal ADD-ACTBK<0:m>, and the refresh bank address signal ADD-REFBK<0:m>, may generate a refresh address signal in response to the refresh command REF, and may output, as the row address signal ADD-ROW<0:n>, a signal selected between the active address signal and the refresh address signal according to the active command ACT.

The address latch circuit 103 may receive the row address signal ADD-ROW<0:n>, the plurality of row active signals RACT<0:n>, and the plurality of timing-adjusted row active signals IRACT<0:n>, and may output a timing-adjusted row address signal IADD-ROW<0:n>.

The address latch circuit 103 may latch the row address signal ADD-ROW<0:n> according to the plurality of row active signals RACT<0:n>, and may output the latched signals as the timing-adjusted row address signal IADD-ROW<0:n> according to the plurality of timing-adjusted row active signals IRACT<0:n>.

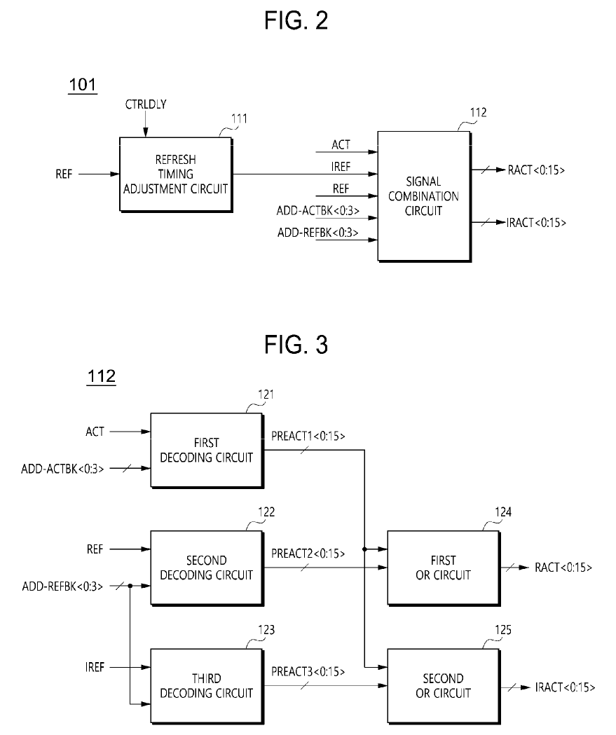

FIG. 2 is a diagram illustrating a configuration of the active signal generation circuit 101 of FIG. 1.

FIG. 2 illustrates an example configuration of the active signal generation circuit 101 in an embodiment where the semiconductor memory apparatus includes sixteen memory banks.

Referring to FIG. 2, the active signal generation circuit 101 may include a refresh timing adjustment circuit 111 and a signal combination circuit 112.

The refresh timing adjustment circuit 111 may receive the refresh command REF and the delay control signal CTRLDLY, and may output a timing-adjusted refresh command IREF. In an embodiment, the refresh timing adjustment circuit 111 may output, as the timing-adjusted refresh command IREF, a signal obtained by adjusting the timing of the refresh command REF by a predetermined time according to the delay control signal CTRLDLY. In an embodiment, the refresh timing adjustment circuit 111 may output, as the timing-adjusted refresh command IREF, a signal obtained by delaying the refresh command REF by a predetermined delay time according to the delay control signal CTRLDLY. The words “predetermined” and “preset” as used herein with respect to a parameter, such as a predetermined timing, time, delay time, address or voltage level or preset timing, time, delay time, address or voltage level, means that a value for the parameter is determined prior to the parameter being used in a process or algorithm. For some embodiments, the value for the parameter is determined before the process or algorithm begins. In other embodiments, the value for the parameter is determined during the process or algorithm but before the parameter is used in the process or algorithm.

The refresh timing adjustment circuit 111 may include a delay circuit in which a delay time is variable according to the delay control signal CTRLDLY. The refresh timing adjustment circuit 111 may generate the timing-adjusted refresh command IREF by delaying the refresh command REF through the delay circuit.

The delay control signal CTRLDLY may be used to adjust the delay time of the delay circuit by a duration corresponding to a timing margin between an active operation and a refresh operation for different memory banks as predefined in an operation specification. An operation of adjusting a value of the delay control signal CTRLDLY to conform to the operation specification may be automatically performed during an initial operation interval of the semiconductor apparatus. It is also possible to adjust the value of the delay control signal CTRLDLY by using a test mode signal as the delay control signal CTRLDLY.

The signal combination circuit 112 may receive the active command ACT, the refresh command REF, the timing-adjusted refresh command IREF, an active bank address signal ADD-ACTBK<0:3>, and a refresh bank address signal ADD-REFBK<0:3>, and may output a plurality of row active signals RACT<0:15> and a plurality of timing-adjusted row active signals IRACT<0:15>.

Each signal bit of the plurality of row active signals RACT<0:15> and the plurality of timing-adjusted row active signals IRACT<0:15> may correspond to one of the sixteen memory banks. For example, the first row active signal RACT<0> and the first timing-adjusted row active signal IRACT<0> may be used to activate the first memory bank, the second row active signal RACT<1> and the second timing-adjusted row active signal IRACT<1> may be used to activate the second memory bank, and the sixteenth row active signal RACT<15> and the sixteenth timing-adjusted row active signal IRACT<15> may be used to activate the sixteenth memory bank.

The signal combination circuit 112 may generate the plurality of row active signals RACT<0:15> and the plurality of timing-adjusted row active signals IRACT<0:15> by selectively combining a signal obtained by decoding the active bank address signal ADD-ACTBK<0:3> according to the active command ACT, a signal obtained by decoding the refresh bank address signal ADD-REFBK<0:3> according to the refresh command REF, and a signal obtained by decoding the refresh bank address signal ADD-REFBK<0:3> according to the timing-adjusted refresh command IREF.

FIG. 3 is a diagram illustrating a configuration of the signal combination circuit 112 of FIG. 2.

Referring to FIG. 3, the signal combination circuit 112 may include a first decoding circuit 121, a second decoding circuit 122, a third decoding circuit 123, a first OR circuit 124, and a second OR circuit 125.

The first decoding circuit 121 may receive the active command ACT and the active bank address signal ADD-ACTBK<0:3>, and may output a plurality of first preliminary active signals PREACT1<0:15>. The first decoding circuit 121 may generate the plurality of first preliminary active signals PREACT1<0:15> by decoding the active bank address signal ADD-ACTBK<0:3> when the active command ACT is activated.

The second decoding circuit 122 may receive the refresh command REF and the refresh bank address signal ADD-REFBK<0:3>, and may output a plurality of second preliminary active signals PREACT2<0:15>. The second decoding circuit 122 may generate the plurality of second preliminary active signals PREACT2<0:15> by decoding the refresh bank address signal ADD-REFBK<0:3> when the refresh command REF is activated.

The third decoding circuit 123 may receive the timing-adjusted refresh command IREF and the refresh bank address signal ADD-REFBK<0:3>, and may output a plurality of third preliminary active signals PREACT3<0:15>. The third decoding circuit 123 may generate the plurality of third preliminary active signals PREACT3<0:15> by decoding the refresh bank address signal ADD-REFBK<0:3> when the timing-adjusted refresh command IREF is activated.

The first OR circuit 124 may receive the plurality of first preliminary active signals PREACT1<0:15> and the plurality of second preliminary active signals PREACT2<0:15>, and may output the plurality of row active signals RACT<0:15>. The first OR circuit 124 may output, as the plurality of row active signals RACT<0:15>, a result obtained by performing an OR operation on the plurality of first preliminary active signals PREACT1<0:15> and the plurality of second preliminary active signals PREACT2<0:15>.

The second OR circuit 125 may receive the plurality of first preliminary active signals PREACT1<0:15> and the plurality of third preliminary active signals PREACT3<0:15>, and may output the plurality of timing-adjusted row active signals IRACT<0:15>. The second OR circuit 125 may output, as the plurality of timing-adjusted row active signals IRACT<0:15>, a result obtained by performing an OR operation on the plurality of first preliminary active signals PREACT1<0:15> and the plurality of third preliminary active signals PREACT3<0:15>.

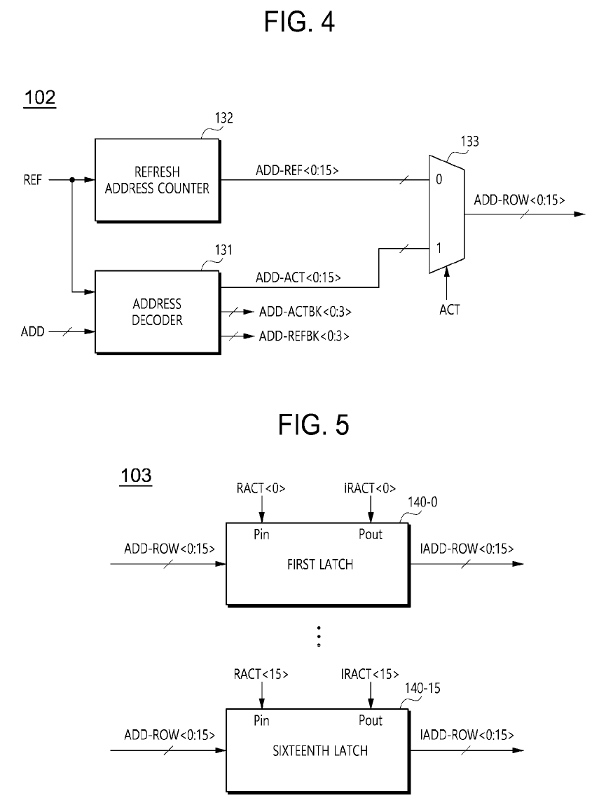

FIG. 4 is a diagram illustrating a configuration of the address control circuit 102 of FIG. 1.

Referring to FIG. 4, the address control circuit 102 may include a refresh address counter 132, an address decoder 131, and a multiplexer 133.

The refresh address counter 132 may count a preset address according to the refresh command REF and may generate a refresh address signal ADD-REF<0:15>.

The address decoder 131 may receive the address signal ADD and the refresh command REF, and may output an active address signal ADD-ACT<0:15>, an active bank address signal ADD-ACTBK<0:3>, and the refresh bank address signal ADD-REFBK<0:3>. The address decoder 131 may decode the address signal ADD to generate the active address signal ADD-ACT<0:15> and the active bank address signal ADD-ACTBK<0:3>. When the refresh command REF is input, the address decoder 131 may decode the address signal ADD to generate the refresh bank address signal ADD-REFBK<0:3>.

The multiplexer 133 may select either the active address signal ADD-ACT<0:15> or the refresh address signal ADD-REF<0:15> according to the active command ACT and may output the selected signal as a row address signal ADD-ROW<0:15>. When the active command ACT is at a logic high level, the multiplexer 133 may output the active address signal ADD-ACT<0:15> as the row address signal ADD-ROW<0:15>. When the active command ACT is at a logic low level, the multiplexer 133 may output the refresh address signal ADD-REF<0:15> as the row address signal ADD-ROW<0:15>.

FIG. 5 is a diagram illustrating a configuration of the address latch circuit 103 of FIG. 1.

Referring to FIG. 5, the address latch circuit 103 may include a plurality of latches 140-0 to 140-15. The plurality of latches 140-0 to 140-15 may be included in a memory core region, that is, a memory bank region.

The first latch 140-0 may latch the row address signal ADD-ROW<0:15> in response to the first row active signal RACT<0>, and may output the latched signal as the timing-adjusted row address signal IADD-ROW<0:15> in response to the first timing-adjusted row active signal IRACT<0>.

The sixteenth latch 140-15 may latch the row address signal ADD-ROW<0:15> in response to the sixteenth row active signal RACT<15>, and may output the latched signal as the timing-adjusted row address signal IADD-ROW<0:15> in response to the sixteenth timing-adjusted row active signal IRACT<15>.

Although not illustrated, the second to fifteenth latches 140-1 to 140-14 may also, similarly to the first latch 140-0 and the sixteenth latch 140-15, latch the row address signal ADD-ROW<0:15> in response to corresponding signals among the plurality of row active signals RACT<1:14>, and may output the latched signals as the timing-adjusted row address signals IADD-ROW<0:15> in response to corresponding signals among the plurality of timing-adjusted row active signals IRACT<1:14>.

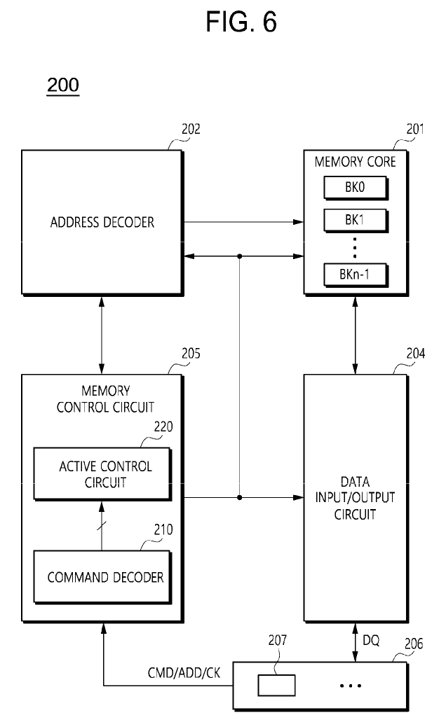

FIG. 6 is a diagram illustrating a configuration of a semiconductor memory apparatus 200 according to an embodiment of the present disclosure.

Referring to FIG. 6, the semiconductor memory apparatus 200 may include a memory core 201, an address decoder 202, a data input/output circuit 204, a memory control circuit 205, and an input/output pad block 206.

The memory core 201 may include a plurality of memory cells, and the plurality of memory cells may be divided into a plurality of unit memory regions, for example, a plurality of memory banks BK0 to BKn−1.

The address decoder 202 may be configured in substantially the same manner as the address decoder 131 described with reference to FIG. 4, and may decode the address signal ADD to generate the active address signal ADD-ACT<0:15>, the active bank address signal ADD-ACTBK<0:3>, and the refresh bank address signal ADD-REFBK<0:3>.

The data input/output circuit 204 may input and output data to and from an external device and the memory core 201.

The memory control circuit 205 may be coupled to the memory core 201, the address decoder 202, and the data input/output circuit 204. The memory control circuit 205 may receive a command CMD, an address signal ADD, and a clock signal CK.

The memory control circuit 205 may include a command decoder 210 and an active control circuit 220. The command decoder 210 may decode the command CMD to generate the active command ACT and the refresh command REF. The active control circuit 220 may be configured in substantially the same manner as the active control circuit 100 described with reference to FIGS. 1-4.

The input/output pad block 206 may receive the command CMD, the address signal ADD, and the clock signal CK, and may include a plurality of pads 207 for inputting and outputting data DQ.

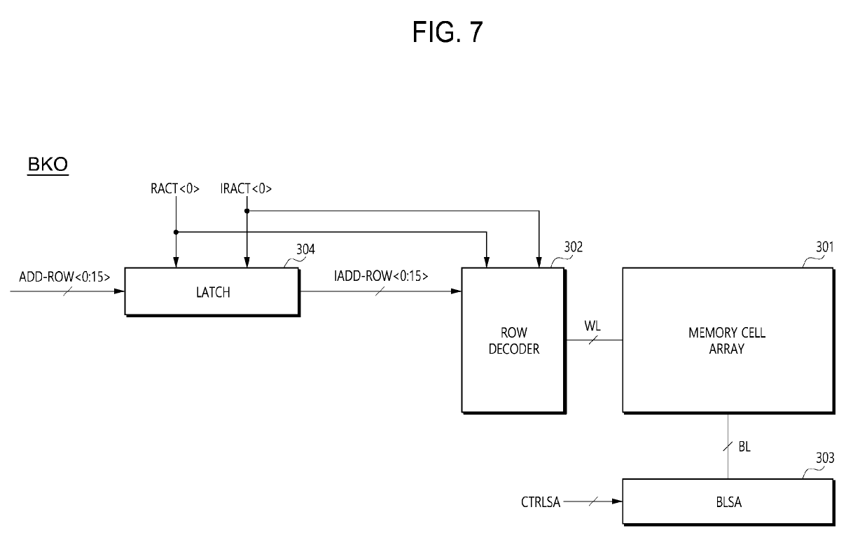

FIG. 7 is a diagram illustrating a configuration of the memory bank BK0 of FIG. 6.

Referring to FIG. 7, the memory bank BK0 may include a memory cell array 301, a row decoder 302, a bitline sense amplifier BLSA 303, and a latch 304.

The memory cell array 301 may include a plurality of wordlines WL and a plurality of bitlines BL, coupled to a plurality of memory cells.

The row decoder 302 may activate a wordline corresponding to the timing-adjusted row address signal IADD-ROW<0:15> among the plurality of wordlines WL when either the first row active signal RACT<0> or the first timing-adjusted row active signal IRACT<0> is activated.

The bitline sense amplifier 303 may sense and amplify signals of the plurality of bitlines BL according to a sense amplifier control signal CTRLSA. As the sense amplifier control signal CTRLSA, the first timing-adjusted row active signal IRACT<0> or a signal obtained by adjusting a timing of the first timing-adjusted row active signal IRACT<0> may be used.

The latch 304 may latch the row address signal ADD-ROW<0:15> according to the first row active signal RACT<0>, and may output the latched signal as the timing-adjusted row address signal IADD-ROW<0:15> according to the first timing-adjusted row active signal IRACT<0>.

An operation of the semiconductor memory apparatus 200 configured as described above will now be described.

For example, an operation will be described in an embodiment where the active command ACT is input for the first memory bank BK0 among the plurality of memory banks BK0 to BKn−1.

When the active command ACT is input, the first row active signal RACT<0> and the first timing-adjusted row active signal IRACT<0> may be activated at the same timing (see FIG. 3).

Because the first row active signal RACT<0> and the first timing-adjusted row active signal IRACT<0> are activated at the same timing, the row address signal ADD-ROW<0:15> may be output as the timing-adjusted row address signal IADD-ROW<0:15> without delay (see FIG. 7).

The row decoder 302 may perform a row active operation by activating a wordline corresponding to the timing-adjusted row address signal IADD-ROW<0:15> among the plurality of wordlines WL in response to an activation of the first timing-adjusted row active signal IRACT<0>.

In addition, the bitline sense amplifier 303 may sense and amplify a signal of a bitline according to the sense amplifier control signal CTRLSA.

As another example, an operation will be described in an embodiment where the refresh command REF is input for the first memory bank BK0 among the plurality of memory banks BK0 to BKn−1.

When the refresh command REF is input, the first row active signal RACT<0> is activated, and the first timing-adjusted row active signal IRACT<0> may be activated after a predetermined time (see FIG. 3).

Because the first timing-adjusted row active signal IRACT<0> is activated at a timing delayed relative to the first row active signal RACT<0>, the row address signal ADD-ROW<0:15> may be output as the timing-adjusted row address signal IADD-ROW<0:15> at a timing of activation of the first timing-adjusted row active signal IRACT<0> (see FIG. 7).

The row decoder 302 performs a row active operation by activating a wordline corresponding to the timing-adjusted row address signal IADD-ROW<0:15> among the plurality of wordlines WL in response to an activation of the first timing-adjusted row active signal IRACT<0>.

In addition, the bitline sense amplifier 303 may sense and amplify a signal of a bitline according to the sense amplifier control signal CTRLSA, whereby a refresh operation for the first memory bank BK0 may be performed.

As yet another example, an operation will be described in an embodiment where the active command ACT for the first memory bank BK0, the refresh command REF for the second memory bank BK1, and the active command ACT for the third memory bank BK2 are sequentially input among the plurality of memory banks BK0 to BKn−1.

After the active command ACT for the first memory bank BK0 is input, the refresh command REF for the second memory bank BK1 is input after a first time defined in an operation specification, and after the refresh command REF for the second memory bank BK1 is input, the active command ACT for the third memory bank BK2 is input after a second time defined in the operation specification. The first time is set shorter than the second time.

The first memory bank BK0 performs a row active operation in response to the active command ACT.

The second memory bank BK1 performs a refresh operation at a delayed timing according to the second timing-adjusted row active signal IRACT<1> when the refresh command REF is input.

Subsequently, the third memory bank BK2 performs a row active operation in response to the active command ACT.

As described above, in an embodiment of the present disclosure, the second memory bank BK1 performs a refresh operation at a delayed timing when the refresh command REF is input. In addition, because the plurality of memory banks BK0 to BKn−1 store the row address signal ADD-ROW<0:n> through the address latch circuit 103 until activation timings of the plurality of timing-adjusted row active signals IRACT<0:n>, an address conflict problem during active and refresh operation intervals can also be resolved.

Accordingly, various embodiments of the present disclosure may prevent or mitigate issues such as power noise caused by overlapping operation intervals of bitline sense amplifiers in different memory banks by compensating for an insufficient timing margin defined by the first time.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the provided descriptions. All changes within the meaning and range of equivalency of the claims are included within their scope.

What is claimed is:

1. An active control circuit, comprising:
an active signal generation circuit configured to generate a plurality of row active signals and a plurality of timing-adjusted row active signals by selectively combining an active command, a timing-adjusted refresh command, an active bank address signal, and a refresh bank address signal; and
an address control circuit configured to generate an active address signal, the active bank address signal, the refresh bank address signal, and a refresh address signal according to an address signal and a refresh command, and configured to output, according to the active command, a signal selected from the active address signal and the refresh address signal as a row address signal.

2. The active control circuit of claim 1, wherein the active signal generation circuit comprises:
a refresh timing adjustment circuit configured to output, as the timing-adjusted refresh command, a signal obtained by delaying the refresh command by a predetermined delay time according to a delay control signal; and
a signal combination circuit configured to selectively combine a signal obtained by decoding the active bank address signal according to the active command, a signal obtained by decoding the refresh bank address signal according to the refresh command, and a signal obtained by decoding the refresh bank address signal according to the timing-adjusted refresh command to generate the plurality of row active signals and the plurality of timing-adjusted row active signals.

3. The active control circuit of claim 2, wherein the refresh timing adjustment circuit comprises a delay circuit, and the delay circuit is configured to adjust a delay time of the delay circuit by an amount of time corresponding to a timing margin between an active operation and a refresh operation for different memory banks set in an operation specification, according to the delay control signal.

4. The active control circuit of claim 3, wherein an operation of adjusting a value of the delay control signal to match the operation specification is automatically performed during an initial operation interval of a semiconductor apparatus, or the value of the delay control signal is adjusted using a test mode signal.

5. The active control circuit of claim 2, wherein the signal combination circuit comprises:
a first decoding circuit configured to decode the active bank address signal to generate a plurality of first preliminary active signals when the active command is activated;
a second decoding circuit configured to decode the refresh bank address signal to generate a plurality of second preliminary active signals when the refresh command is activated;
a third decoding circuit configured to decode the refresh bank address signal to generate a plurality of third preliminary active signals when the timing-adjusted refresh command is activated;
a first OR circuit configured to output a result obtained by performing an OR operation on the plurality of first preliminary active signals and the plurality of second preliminary active signals as the plurality of row active signals; and
a second OR circuit configured to output a result obtained by performing an OR operation on the plurality of first preliminary active signals and the plurality of third preliminary active signals as the plurality of timing-adjusted row active signals.

6. The active control circuit of claim 1, wherein the address control circuit comprises:
a refresh address counter configured to generate the refresh address signal by counting a preset address according to the refresh command;
an address decoder configured to decode the address signal to generate the active address signal, the active bank address signal, and the refresh bank address signal; and
a multiplexer configured to select either the active address signal or the refresh address signal according to the active command and configured to output the selected signal as the row address signal.

7. The active control circuit of claim 1, further comprising an address latch circuit configured to latch the row address signal according to the plurality of row active signals, and configured to output the latched signals as a timing-adjusted row address signal according to the plurality of timing-adjusted row active signals.

8. The active control circuit of claim 1, wherein the timing-adjusted refresh command is generated by delaying the refresh command.

9. A semiconductor memory apparatus, comprising:
a plurality of memory banks configured to perform a row active operation corresponding to a row address signal according to a plurality of row active signals and a plurality of timing-adjusted row active signals; and
an active control circuit configured to selectively combine an active command, a timing-adjusted refresh command, an active bank address signal, and a refresh bank address signal to generate the plurality of row active signals and the plurality of timing-adjusted row active signals.

10. The semiconductor memory apparatus of claim 9, wherein each of the plurality of memory banks comprises:
a memory cell array in which a plurality of wordlines and a plurality of bitlines are arranged;
a latch configured to latch the row address signal according to a first row active signal among the plurality of row active signals, and configured to output the latched signal as a timing-adjusted row address signal according to a first timing-adjusted row active signal among the plurality of timing-adjusted row active signals; and
a row decoder configured to activate a wordline corresponding to the timing-adjusted row address signal among the plurality of wordlines when at least one of the first row active signal and the first timing-adjusted row active signal is activated.

11. The semiconductor memory apparatus of claim 10, further comprising a bitline sense amplifier configured to sense and amplify signals of the plurality of bitlines according to a sense amplifier control signal generated based on the first timing-adjusted row active signal.

12. The semiconductor memory apparatus of claim 9, wherein the active signal generation circuit comprises:
a refresh timing adjustment circuit configured to output, as the timing-adjusted refresh command, a signal obtained by delaying a refresh command by a predetermined delay time according to a delay control signal;
a signal combination circuit configured to selectively combine a signal obtained by decoding the active bank address signal according to the active command, a signal obtained by decoding the refresh bank address signal according to the refresh command, and a signal obtained by decoding the refresh bank address signal according to the timing-adjusted refresh command to generate the plurality of row active signals and the plurality of timing-adjusted row active signals; and
an address latch circuit configured to latch the row address signal according to the plurality of row active signals, and configured to output the latched signals as a timing-adjusted row address signal according to the plurality of timing-adjusted row active signals.

13. The semiconductor memory apparatus of claim 9, wherein the timing-adjusted refresh command is generated by delaying a refresh command.

14. A semiconductor memory apparatus, comprising:
an active control circuit configured to selectively combine an active command, a timing-adjusted refresh command, an active bank address signal, and a refresh bank address signal to generate a plurality of row active signals and a plurality of timing-adjusted row active signals;
a memory cell array in which a plurality of wordlines and a plurality of bitlines are arranged;
a latch configured to latch a row address signal according to a first row active signal among the plurality of row active signals, and configured to output the latched signal as a timing-adjusted row address signal according to a first timing-adjusted row active signal among the plurality of timing-adjusted row active signals; and
a row decoder configured to activate a wordline corresponding to the timing-adjusted row address signal among the plurality of wordlines when at least one of the first row active signal and the first timing-adjusted row active signal is activated.

15. The semiconductor memory apparatus of claim 14, wherein the active control circuit comprises:
a refresh timing adjustment circuit configured to output, as the timing-adjusted refresh command, a signal obtained by delaying a refresh command by a predetermined delay time according to a delay control signal;
a signal combination circuit configured to selectively combine a signal obtained by decoding the active bank address signal according to the active command, a signal obtained by decoding the refresh bank address signal according to the refresh command, and a signal obtained by decoding the refresh bank address signal according to the timing-adjusted refresh command to generate the plurality of row active signals and the plurality of timing-adjusted row active signals;
an address latch circuit configured to latch the row address signal according to the plurality of row active signals, and configured to output the latched signals as the timing-adjusted row address signal according to the plurality of timing-adjusted row active signals.

16. The semiconductor memory apparatus of claim 15, wherein the refresh timing adjustment circuit comprises a delay circuit, and the delay circuit is configured to adjust a delay time of the delay circuit by an amount of time corresponding to a timing margin between an active operation and a refresh operation for different memory banks set in an operation specification, according to the delay control signal.

17. The semiconductor memory apparatus of claim 16, wherein an operation of adjusting a value of the delay control signal to match the operation specification is automatically performed during an initial operation interval of a semiconductor apparatus, or the value of the delay control signal is adjusted using a test mode signal.

18. The semiconductor memory apparatus of claim 15, wherein the signal combination circuit comprises:
a first decoding circuit configured to decode the active bank address signal to generate a plurality of first preliminary active signals when the active command is activated;
a second decoding circuit configured to decode the refresh bank address signal to generate a plurality of second preliminary active signals when a refresh command is activated;
a third decoding circuit configured to decode the refresh bank address signal to generate a plurality of third preliminary active signals when the timing-adjusted refresh command is activated;
a first OR circuit configured to output a result obtained by performing an OR operation on the plurality of first preliminary active signals and the plurality of second preliminary active signals as the plurality of row active signals; and
a second OR circuit configured to output a result obtained by performing an OR operation on the plurality of first preliminary active signals and the plurality of third preliminary active signals as the plurality of timing-adjusted row active signals.

19. The semiconductor memory apparatus of claim 14, further comprising a bitline sense amplifier configured to sense and amplify signals of the plurality of bitlines according to a sense amplifier control signal generated based on the plurality of timing-adjusted row active signals.

20. The semiconductor memory apparatus of claim 14, wherein the timing-adjusted refresh command is generated by delaying a refresh command.
